(19) United States
(12) Patent Application Publication
(10) Pub. No.: US 2024/0163615 A1
(43) Pub. Date: May 16, 2024

(54) PIEZOELECTRIC FILM AND LAMINATED PIEZOELECTRIC ELEMENT

(71) Applicant: FUJIFILM Corporation, Tokyo (JP)

(72) Inventor: Hideaki TAKEKUMA, Minamiashigara-shi (JP)

(73) Assignee: FUJIFILM Corporation, Tokyo (JP)

(21) Appl. No.: 18/422,864

(22) Filed: Jan. 25, 2024

Related U.S. Application Data
(63) Continuation of application No. PCT/JP2022/027994, filed on Jul. 19, 2022.

(30) Foreign Application Priority Data
Aug. 18, 2021 (JP) 2021-133105

(51) Int. Cl. H04R 17/00; H10N 30/092; H10N 30/85; H10N 30/88

(52) U.S. Cl. CPC H04R 17/00; H10N 30/092; H10N 30/852; H10N 30/883

(57) ABSTRACT

An object of the present invention is to provide a piezoelectric film in which a high sound pressure can be obtained in a case of, for example, being formed into a piezoelectric speaker, and a laminated piezoelectric element obtained by laminating the piezoelectric films. The object is achieved with a piezoelectric film including a piezoelectric layer which contains piezoelectric particles in a matrix containing a polymer material, electrode layers which are provided on both surfaces of the piezoelectric layer, and protective layers which cover the electrode layers, in which, in a case where “ratio D of elastic recovery amount=(elastic recovery amount of piezoelectric layer/elastic recovery amount of protective layer)” is determined in an elastic recovery amount measured by a nanoindentation measurement, the ratio D of the elastic recovery amount satisfies “0.27≤D≤1.19”.

### CROSS-REFERENCE TO RELATED APPLICATIONS

This application is a Continuation of PCT International Application No. PCT/JP2022/027994 filed on Jul. 19, 2022, which claims priority under 35 U.S.C. § 119(a) to Japanese Patent Application No. 2021-133105 filed on Aug. 18, 2021. The above applications are hereby expressly incorporated by reference, in their entirety, into the present application.

### BACKGROUND OF THE INVENTION

### 1. Field of the Invention

The present invention relates to a piezoelectric film used as an electroacoustic conversion film or the like, and a laminated piezoelectric element obtained by laminating the piezoelectric films.

### 2. Description of the Related Art

Flexible displays, such as an organic EL display, which include a flexible substrate such as plastic have been developed.

In a case where such a flexible display is used as an image display device also serving as a sound generator which reproduces a sound together with an image, such as a television receiver, a speaker which is an acoustic device for generating the sound is required.

Examples of a typical shape of the speaker in the related art include a funnel-like so-called cone shape and a spherical dome shape. However, in a case where such a speaker is intended to be incorporated in the above-described flexible display, there is a concern that lightness and flexibility, which are advantages of the flexible display, are impaired. In addition, in a case where the speaker is attached externally, since the speaker is troublesome to carry and difficult to install on a curved wall, there is a concern that an appearance is impaired.

Meanwhile, a piezoelectric film with flexibility has been suggested as a speaker which can be integrated with the flexible display without impairing the lightness and the flexibility.

For example, JP2014-014063A discloses a piezoelectric film (electroacoustic conversion film) including a piezoelectric layer (polymer-based piezoelectric composite material) obtained by dispersing piezoelectric particles in a viscoelastic matrix composed of a polymer material having viscoelasticity at normal temperature, electrode layers (thin film electrode) provided on both surfaces of the piezoelectric layer, and a protective layer provided on a surface of the electrode layer.

### SUMMARY OF THE INVENTION

The piezoelectric layer disclosed in JP2014-014063A has excellent piezoelectric characteristics. In addition, the piezoelectric layer is obtained by dispersing piezoelectric particles such as lead zirconate titanate particles in a polymer material such as cyanoethylated polyvinyl alcohol, and thus has favorable flexibility.

Therefore, according to the piezoelectric film including the piezoelectric layer, it is possible to obtain an electroacoustic conversion film or the like having flexibility and favorable piezoelectric characteristics, which can be used in, for example, a flexible speaker as a piezoelectric speaker.

In such a piezoelectric film, in a case where a voltage is applied to the piezoelectric layer by energizing the electrode layer, the piezoelectric layer (piezoelectric film) is stretched and contracted by an action of the piezoelectric particles, and the stretch and contraction are converted into a vibration in a thickness direction to output a sound, for example.

Therefore, in order to operate the piezoelectric film properly, it is preferable that the electrode and the piezoelectric layer are closely attached with each other over the entire surface without interlayer peeling between the electrode and the piezoelectric layer. In a case where the interlayer peeling is present between the electrode and the piezoelectric layer, a loss occurs in a case where the vibration of the piezoelectric layer is transmitted. As a result, an inconvenience such as a decrease in sound pressure occurs in, for example, sound output.

In addition, in the piezoelectric film, it is preferable that the electrode layer has no defects such as cracking and breakage in order to operate properly. In a case where the electrode layer has cracking and breakage, similarly, a loss occurs in a case where the vibration of the piezoelectric layer is transmitted. As a result, an inconvenience such as a decrease in sound pressure occurs in, for example, sound output.

However, in the piezoelectric film of the related art, it is inevitable that there is a lot of interlayer peeling between the piezoelectric layer and the electrode and cracking and breakage occur in the electrode layer, and thus further improvement is desired.

An object of the present invention is to solve such problems of the related art, and to provide a piezoelectric film including electrode layers on both surfaces of a piezoelectric layer which contains piezoelectric particles in a matrix containing a polymer material, in which, for example, in a case of being formed into a piezoelectric speaker, a high sound pressure is obtained, and provide a laminated piezoelectric element obtained by laminating the piezoelectric films.

In order to achieve the above-described objects, the present invention has the following configurations.

[1] A piezoelectric film comprising:
a piezoelectric layer which contains piezoelectric particles in a matrix containing a polymer material;
electrode layers which are provided on both surfaces of the piezoelectric layer; and
protective layers which are provided on surfaces of the electrode layers,
in which, in a case where a ratio D between an elastic recovery amount of the piezoelectric layer and an elastic recovery amount of the protective layer, which are obtained by a nanoindentation measurement, is determined as “ratio D of elastic recovery amount=elastic recovery amount of piezoelectric layer/elastic recovery amount of protective layer”, the ratio D of the elastic recovery amount satisfies

0.27≤D≤1.19.

[2] The piezoelectric film according to [1],
in which the ratio D of the elastic recovery amount satisfies

0.35≤D≤1.19.

[3] The piezoelectric film according to [1] or [2],
in which a thickness of the electrode layer is 20 nm or more.

[4] The piezoelectric film according to any one of [1] to [3],
in which the piezoelectric film is polarized in a thickness direction.

[5] The piezoelectric film according to any one of [1] to [4],
in which the polymer material is a polymer material having a cyanoethyl group.

[6] The piezoelectric film according to [5],
in which the polymer material is cyanoethylated polyvinyl alcohol.

[7] A laminated piezoelectric element obtained by laminating a plurality of layers of the piezoelectric films according to any one of [1] to [6].

[8] The laminated piezoelectric element according to [7],
in which the piezoelectric film is polarized in a thickness direction, and
polarization directions of adjacent piezoelectric films are opposite to each other.

[9] The laminated piezoelectric element according to [7] or [8],
in which the plurality of layers of the piezoelectric films are laminated by folding the piezoelectric film one or more times.

[10] The laminated piezoelectric element according to any one of [7] to [9], further comprising:
a bonding layer which bonds adjacent piezoelectric films.

According to the present invention, it is possible to obtain a piezoelectric film including electrode layers on both surfaces of a piezoelectric layer which contains piezoelectric particles in a matrix containing a polymer material, in which, for example, in a case of being formed into a piezoelectric speaker, a high sound pressure is obtained.

### BRIEF DESCRIPTION OF THE DRAWINGS

FIG. 1 is a conceptual view showing an example of the piezoelectric film according to the embodiment of the present invention.

FIG. 2 is a conceptual view for describing a nanoindentation measurement.

FIG. 3 is a conceptual view for describing an example of a production method of the piezoelectric film.

FIG. 4 is a conceptual view for describing the example of the production method of the piezoelectric film.

FIG. 5 is a conceptual view for describing the example of the production method of the piezoelectric film.

FIG. 6 is a conceptual view for describing the example of the production method of the piezoelectric film.

FIG. 7 is a conceptual view for describing the example of the production method of the piezoelectric film.

FIG. 8 is a conceptual view for describing the example of the production method of the piezoelectric film.

FIG. 9 is a conceptual view showing an example of a piezoelectric speaker including the piezoelectric film shown in FIG. 1.

FIG. 10 is a conceptual view for describing a method of measuring a sound pressure in Examples.

### DESCRIPTION OF THE PREFERRED EMBODIMENTS

Hereinafter, the piezoelectric film and the laminated piezoelectric element according to the embodiment of the present invention will be described in detail based on suitable examples shown in the accompanying drawings.

Although configuration requirements to be described below are described based on representative embodiments of the present invention, the present invention is not limited to the embodiments.

Any numerical range expressed using “to” in the present specification refers to a range including the numerical values before and after the “to” as a lower limit value and an upper limit value, respectively.

In addition, the drawings shown below are conceptual views for describing the present invention, and the thickness of each layer, the size of the piezoelectric particles, the size of the constituent members, and the like are different from the actual values.

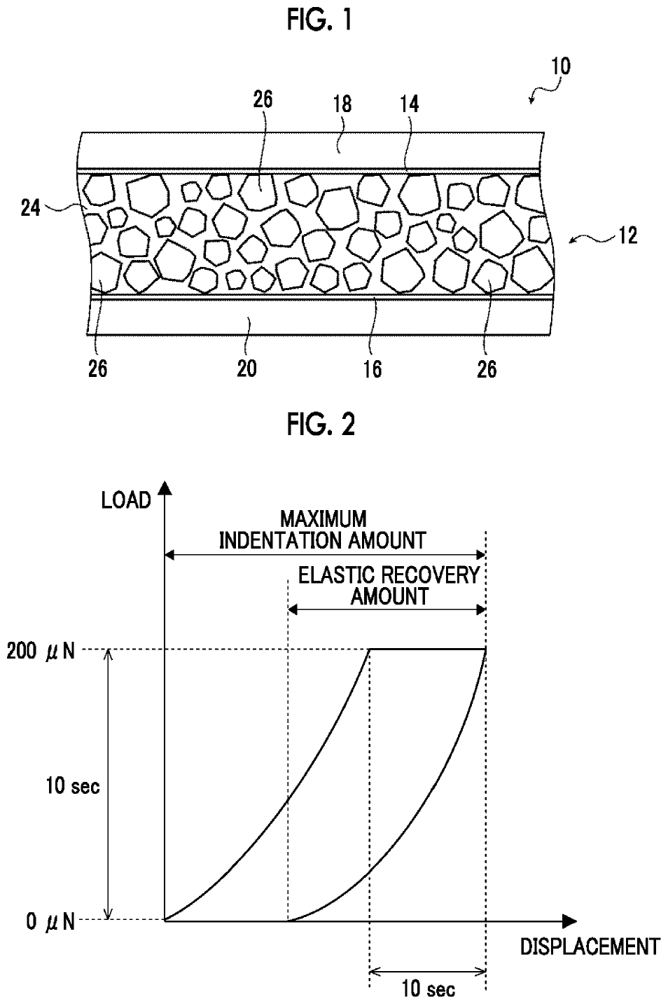

FIG. 1 conceptually shows an example of the piezoelectric film according to the embodiment of the present invention.

As shown in FIG. 1, a piezoelectric film 10 includes a piezoelectric layer 12, a first electrode layer 14 laminated on one surface of the piezoelectric layer 12, a first protective layer 18 laminated on a surface of the first electrode layer 14, a second electrode layer 16 laminated on the other surface of the piezoelectric layer 12, and a second protective layer 20 laminated on a surface of the second electrode layer 16.

In the piezoelectric film 10, the piezoelectric layer 12 contains piezoelectric particles 26 in a matrix 24 containing a polymer material, as conceptually shown in FIG. 1.

Here, in the piezoelectric film 10 according to the embodiment of the present invention, in a case where a ratio D between an elastic recovery amount of the piezoelectric layer 12 and an elastic recovery amount of the protective layer, which are obtained by a nanoindentation measurement, is determined as “ratio D of elastic recovery amount=elastic recovery amount of piezoelectric layer/elastic recovery amount of protective layer”, the ratio D of the elastic recovery amount satisfies

0.27≤D≤1.19,

preferably

0.35≤D≤1.19.

Since the piezoelectric film 10 according to the embodiment of the present invention has such a configuration, interlayer peeling partially existing between the first electrode layer 14 and the piezoelectric layer 12 and between the second electrode layer 16 and the piezoelectric layer 12 can be significantly reduced, and further, cracking and breakage of the first electrode layer 14 and the second electrode layer can be significantly reduced. This will be described in detail later.

In the present invention, the terms “first” and “second” in the first electrode layer 14 and the second electrode layer 16, and the first protective layer 18 and the second protective layer 20 are used to distinguish two similar members of the piezoelectric film 10 for convenience.

That is, the terms “first” and “second” attached to the constituent elements of the piezoelectric film 10 have no technical meaning, the positions of the two may be reversed, and a protective layer laminated on the first electrode layer may be the second protective layer.

As described above, in the piezoelectric film 10 according to the embodiment of the present invention, the piezoelectric layer 12 is formed by dispersing the piezoelectric particles 26 in the matrix 24 containing a polymer material. That is, the piezoelectric layer 12 is a polymer-based piezoelectric composite material.

Here, it is preferable that the polymer-based piezoelectric composite material (piezoelectric layer 12) satisfies the following requirements. In the present invention, normal temperature is in a range of 0° C. to 50° C.

(i) Flexibility

For example, in a case of being gripped in a state of being loosely bent with a sense of document such as a newspaper and a magazine as a portable device, the polymer-based piezoelectric composite material is continuously subjected to large bending deformation from the outside at a comparatively slow vibration of less than or equal to a few Hz. At this time, in a case where the polymer-based piezoelectric composite material is rigid, large bending stress is generated to that extent, and a crack is generated at an interface between the polymer matrix and the piezoelectric particles, which may lead to breakage. Accordingly, the polymer-based piezoelectric composite material is required to have suitable flexibility. In addition, in a case where strain energy is diffused into the outside as heat, the stress can be relaxed. Therefore, the polymer-based piezoelectric composite material is required to have a suitably large loss tangent.

(ii) Acoustic Quality

In a speaker, the piezoelectric particles vibrate at a frequency of an audio band of 20 Hz to 20 kHz, and vibration energy causes the entire vibration plate (polymer-based piezoelectric composite material) to vibrate integrally so that sound is reproduced. Therefore, in order to increase transmission efficiency of the vibration energy, the polymer-based piezoelectric composite material is required to have appropriate rigidity. In addition, in a case where frequency characteristics of the speaker are smooth, an amount of a change in acoustic quality decreases in a case where the lowest resonance frequency f₀ is changed in association with a change in curvature of the speaker. Therefore, the polymer-based piezoelectric composite material is required to have a suitably large loss tangent.

It has been known that the lowest resonance frequency f₀ of the vibration plate for a speaker is represented by the following expression. Here, s represents the stiffness of the vibration system, and m represents the mass.

$$Lowest resonance frequency {f}_{0} = \frac{1}{2 π} \sqrt{\frac{s}{m}}$$

Here, as a degree of bending of the piezoelectric film, that is, a curvature radius of a bending portion increases, a mechanical stiffness decreases, and thus the lowest resonance frequency f₀ decreases. That is, acoustic quality (volume and frequency characteristics) of the speaker changes depending on the curvature radius of the piezoelectric film.

That is, the flexible polymer-based piezoelectric composite material used as an electroacoustic conversion film is required to exhibit a behavior of being rigid with respect to a vibration of 20 Hz to 20 kHz and being flexible with respect to a vibration of less than or equal to a few Hz. In addition, the loss tangent of the polymer-based piezoelectric composite material is required to be suitably large with respect to the vibration of all frequencies of 20 kHz or less.

In general, a polymer solid has a viscoelasticity relaxing mechanism, and a molecular movement with a large scale is observed as a decrease (relief) in a storage elastic modulus (Young's modulus) or a maximal value (absorption) in a loss elastic modulus along with an increase in temperature or a decrease in frequency. Among these, the relaxation due to a microbrown movement of a molecular chain in an amorphous region is referred to as main dispersion, and an extremely large relaxing phenomenon is observed. A temperature at which this main dispersion occurs is a glass transition point (Tg), and the viscoelasticity relaxing mechanism is most remarkably observed.

In the polymer-based piezoelectric composite material (piezoelectric layer 12), the polymer-based piezoelectric composite material exhibiting a behavior of being rigid with respect to the vibration of 20 Hz to 20 kHz and being flexible with respect to the slow vibration of less than or equal to a few Hz is achieved by using, as a matrix, a polymer material having a glass transition point at normal temperature, that is, a polymer material having a viscoelasticity at normal temperature. In particular, from the viewpoint that such a behavior is suitably exhibited, it is preferable that a polymer material in which the glass transition point at a frequency of 1 Hz is at normal temperature, that is, in a range of 0° C. to 50° C. is used for a matrix of the polymer-based piezoelectric composite material.

As the polymer material having a viscoelasticity at normal temperature, various known materials can be used. It is preferable that a polymer material in which the maximal value of a loss tangent Tan δ at a frequency of 1 Hz according to a dynamic viscoelasticity test at normal temperature, that is, in a range of 0° C. to 50° C. is 0.5 or more is used as the polymer material.

In this manner, in a case where the polymer-based piezoelectric composite material is slowly bent due to an external force, stress concentration on the interface between the polymer matrix and the piezoelectric particles at the maximum bending moment portion is relaxed, and thus high flexibility can be expected.

In the polymer material having a viscoelasticity at normal temperature, it is preferable that a storage elastic modulus (E′) at a frequency of 1 Hz according to the dynamic viscoelasticity measurement is 100 MPa or more at 0° C. and 10 MPa or less at 50° C.

In this manner, a bending moment generated in a case where the polymer-based piezoelectric composite material is slowly bent due to the external force can be reduced, and at the same time, the polymer-based piezoelectric composite material can exhibit a behavior of being rigid with respect to an acoustic vibration of 20 Hz to 20 kHz.

In addition, it is more suitable that a relative permittivity of the polymer material having a viscoelasticity at normal temperature is 10 or more at 25° C. Accordingly, in a case where a voltage is applied to the polymer-based piezoelectric composite material, a higher electric field is applied to the piezoelectric particles in the polymer matrix, and thus a large deformation amount can be expected.

However, in consideration of ensuring favorable moisture resistance and the like, it is suitable that the relative permittivity of the polymer material is 10 or less at 25° C.

Examples of the polymer material having a viscoelasticity at normal temperature and satisfying such conditions include cyanoethylated polyvinyl alcohol (cyanoethylated PVA), polyvinyl acetate, poly(vinylidene chloride-co-acrylonitrile), a polystyrene-vinyl polyisoprene block copolymer, polyvinyl methyl ketone, and polybutyl methacrylate. In addition, as these polymer materials, a commercially available product such as Hybrar 5127 (manufactured by Kuraray Co., Ltd.) can also be suitably used. Among these, as the polymer material, a material having a cyanoethyl group is preferably used, and cyanoethylated PVA is particularly preferably used.

In the matrix 24, these polymer materials having viscoelasticity at normal temperature may be used alone or in combination (mixture) of a plurality of kinds thereof.

A polymer material having no viscoelasticity at normal temperature may also be added to the matrix 24 as necessary, in addition to the polymer material having a viscoelasticity at normal temperature.

That is, for the purpose of adjusting dielectric characteristics, mechanical characteristics, and the like, other dielectric polymer materials may be added to the matrix 24 as necessary, in addition to the polymer material having viscoelasticity at normal temperature, such as cyanoethylated PVA.

Examples of the dielectric polymer material which can be added thereto include fluorine-based polymers such as polyvinylidene fluoride, a vinylidene fluoride-tetrafluoroethylene copolymer, a vinylidene fluoride-trifluoroethylene copolymer, a polyvinylidene fluoride-trifluoroethylene copolymer, and a polyvinylidene fluoride-tetrafluoroethylene copolymer; polymers having a cyano group or a cyanoethyl group, such as a vinylidene cyanide-vinyl acetate copolymer, cyanoethyl cellulose, cyanoethyl hydroxysaccharose, cyanoethyl hydroxycellulose, cyanoethyl hydroxypullulan, cyanoethyl methacrylate, cyanoethyl acrylate, cyanoethyl hydroxyethyl cellulose, cyanoethyl amylose, cyanoethyl hydroxypropyl cellulose, cyanoethyl dihydroxypropyl cellulose, cyanoethyl hydroxypropyl amylose, cyanoethyl polyacrylamide, cyanoethyl polyacrylate, cyanoethyl pullulan, cyanoethyl polyhydroxymethylene, cyanoethyl glycidol pullulan, cyanoethyl saccharose, and cyanoethyl sorbitol; and synthetic rubber such as nitrile rubber and chloroprene rubber. Among these, a polymer material having a cyanoethyl group is suitably used.

In addition, in the matrix 24 of the piezoelectric layer 12, the number of kinds of the dielectric polymer material to be added in addition to the polymer material having viscoelasticity at normal temperature, such as cyanoethylated PVA, is not limited to one, and a plurality of kinds of the dielectric polymer materials may be added.

In addition, for the purpose of adjusting the glass transition point Tg, a thermoplastic resin such as a vinyl chloride resin, polyethylene, polystyrene, a methacrylic resin, polybutene, and isobutylene, a thermosetting resin such as a phenol resin, a urea resin, a melamine resin, an alkyd resin, and mica, or the like may be added to the matrix 24, in addition to the dielectric polymer material.

Furthermore, for the purpose of improving pressure sensitive adhesiveness, a viscosity imparting agent such as rosin ester, rosin, terpene, terpene phenol, and a petroleum resin may be added to the matrix 24.

In the matrix 24 of the piezoelectric layer 12, an addition amount of materials to be added, other than the polymer material having viscoelasticity at normal temperature, such as cyanoethylated PVA, is not particularly limited, but is preferably set to 30% by mass or less in terms of the proportion of the materials in the matrix 24.

In this manner, characteristics of the polymer material to be added can be exhibited without impairing the viscoelasticity relaxing mechanism in the matrix 24, so that preferred results such as an increase in permittivity, improvement of heat resistance, and improvement of adhesiveness between the piezoelectric particles 26 and the electrode layer can be obtained.

In the piezoelectric film 10 according to the embodiment of the present invention, the piezoelectric layer 12 contains the piezoelectric particles 26 in such a matrix 24. Specifically, the piezoelectric layer 12 is a polymer-based piezoelectric composite material formed by dispersing the piezoelectric particles 26 in the matrix 24.

The piezoelectric particles 26 consist of ceramic particles having a perovskite type or wurtzite type crystal structure.

Examples of the ceramic particles constituting the piezoelectric particles 26 include lead zirconate titanate (PZT), lead lanthanum zirconate titanate (PLZT), barium titanate (BaTiO₃), zinc oxide (ZnO), and a solid solution (BFBT) of barium titanate and bismuth ferrite (BiFe₃).

Only one of these piezoelectric particles 26 may be used, or a plurality of kinds thereof may be used in combination (mixture).

A particle diameter of the piezoelectric particles 26 is not limited, and may be appropriately selected according to the size, applications, and the like of the piezoelectric film 10.

The particle diameter of the piezoelectric particles 26 is preferably 1 to 10 μm. By setting the particle diameter of the piezoelectric particles 26 to be within the above-described range, preferred results in terms of achieving both excellent piezoelectric characteristics and flexibility of the piezoelectric film 10 can be obtained.

In FIG. 1, the piezoelectric particles 26 in the piezoelectric layer 12 are irregularly dispersed in the matrix 24, but the present invention is not limited thereto.

That is, it is preferable that the piezoelectric particles 26 in the piezoelectric layer 12 may be regularly dispersed in the matrix 24 as long as the piezoelectric particles 26 are uniformly dispersed therein.

In addition, the particle diameter of the piezoelectric particles 26 may or may not be uniform.

In the piezoelectric film 10, a ratio between an amount of the matrix 24 and an amount of the piezoelectric particles 26 in the piezoelectric layer 12 is not limited, and may be appropriately set according to the size and the thickness of the piezoelectric film 10 in the plane direction, the applications of the piezoelectric film 10, the characteristics required for the piezoelectric film 10, and the like.

A volume fraction of the piezoelectric particles 26 in the piezoelectric layer 12 is preferably 30% to 80%, more preferably 50% or more, and still more preferably 50% to 80%.

By setting the ratio between the amount of the matrix 24 and the amount of the piezoelectric particles 26 to be within the above-described range, preferred results in terms of achieving both of excellent piezoelectric characteristics and flexibility can be obtained.

A thickness of the piezoelectric layer 12 in the piezoelectric film 10 is not particularly limited, and may be appropriately set according to the applications of the piezoelectric film 10, the characteristics required for the piezoelectric film 10, and the like.

It is advantageous that the thickness of the piezoelectric layer 12 increases large in terms of stiffness such as the strength of rigidity of a so-called sheet-like material, but the voltage (potential difference) required to stretch and contract the piezoelectric film 10 increases by the same amount.

The thickness of the piezoelectric layer 12 is preferably in a range of 8 to 300 μm, more preferably in a range of 20 to 200 μm, still more preferably in a range of 30 to 150 μm, and particularly preferably in a range of 40 to 100 μm.

By setting the thickness of the piezoelectric layer 12 to be within the above-described ranges, preferred results in terms of achieving both ensuring of the rigidity and moderate elasticity can be obtained.

It is preferable that the piezoelectric layer 12, that is, the piezoelectric film 10 is subjected to a polarization treatment (poling) in a thickness direction. The polarization treatment will be described later in detail.

As shown in FIG. 1, the piezoelectric film 10 of the illustrated example has a configuration in which the first electrode layer 14 is provided on one surface of the piezoelectric layer 12, the first protective layer 18 is provided on a surface thereof, the second electrode layer 16 is provided on the other surface of the piezoelectric layer 12, and the second protective layer 20 is provided on a surface thereof.

Here, the first electrode layer 14 and the second electrode layer 16 form an electrode pair. That is, the piezoelectric film 10 has a configuration in which both surfaces of the piezoelectric layer 12 are sandwiched between the electrode pair, and this laminate is sandwiched between the first protective layer 18 and the second protective layer 20.

In such a piezoelectric film 10, a region sandwiched between the first electrode layer 14 and the second electrode layer 16 stretches and contracts according to an applied voltage.

The first protective layer 18 and the second protective layer 20 in the piezoelectric film 10 have a function of coating the first electrode layer 14 and the second electrode layer 16 and imparting moderate rigidity and mechanical strength to the piezoelectric layer 12. That is, the piezoelectric layer 12 consisting of the matrix 24 and the piezoelectric particles 26 in the piezoelectric film 10 exhibits extremely excellent flexibility under bending deformation at a slow vibration, but may have insufficient rigidity or mechanical strength depending on the applications. As a compensation for this, the piezoelectric film 10 includes the first protective layer 18 and the second protective layer 20.

The first protective layer 18 and the second protective layer 20 are not limited and various sheet-like materials can be used, and suitable examples thereof include various resin films.

Among these, from the viewpoint of excellent mechanical characteristics and heat resistance, a resin film consisting of polyethylene terephthalate (PET), polypropylene (PP), polystyrene (PS), polycarbonate (PC), polyphenylene sulfite (PPS), polymethylmethacrylate (PMMA), polyetherimide (PEI), polyimide (PI), polyethylene naphthalate (PEN), triacetyl cellulose (TAC), a cyclic olefin-based resin, and the like is suitably used.

Thicknesses of the first protective layer 18 and the second protective layer 20 are not limited. In addition, the thicknesses of the first protective layer 18 and the second protective layer 20 are basically the same as each other, but may be different from each other.

Here, in a case where the rigidity of the first protective layer 18 and the second protective layer 20 is extremely high, not only is the stretch and contraction of the piezoelectric layer 12 constrained, but also the flexibility is impaired. Therefore, it is advantageous that the thicknesses of the first protective layer 18 and the second protective layer 20 decrease except for the case where the mechanical strength or favorable handleability as a sheet-like material is required.

In a case where the thicknesses of the first protective layer 18 and the second protective layer 20 in the piezoelectric film 10 are ½ times or less the thickness of the piezoelectric layer 12, preferred results in terms of achieving both ensuring of the rigidity and moderate elasticity can be obtained.

For example, in a case where the thickness of the piezoelectric layer 12 is 50 μm and the first protective layer 18 and the second protective layer 20 consist of PET, the thicknesses of the first protective layer 18 and the second protective layer 20 are preferably 25 μm or less, more preferably 20 μm or less, and still more preferably 10 μm or less.

In the piezoelectric film 10, the first electrode layer 14 is formed between the piezoelectric layer 12 and the first protective layer 18. In addition, the second electrode layer 16 is formed between the piezoelectric layer 12 and the second protective layer 20.

The first electrode layer 14 and the second electrode layer 16 are provided to apply a voltage to the piezoelectric layer 12 (piezoelectric film 10).

In the present invention, a material for forming the first electrode layer 14 and the second electrode layer 16 is not limited, and various conductors can be used. Specific examples thereof include metals such as carbon, palladium, iron, tin, aluminum, nickel, platinum, gold, silver, copper, titanium, chromium, and molybdenum, alloys thereof, laminates and composites of these metals and alloys, and indium tin oxide. Among these, copper, aluminum, gold, silver, platinum, or indium tin oxide is suitable as the first electrode layer 14 and the second electrode layer 16.

In addition, a method of forming the first electrode layer 14 and the second electrode layer 16 is not limited, and a known method can be used. Examples thereof include film formation by a vapor-phase deposition method (vacuum film forming method) such as vacuum vapor deposition and sputtering, film formation by plating, and a method of bonding a foil formed of the materials described above.

Among these, particularly from the reason that the flexibility of the piezoelectric film 10 can be ensured, a thin film made of copper, aluminum, or the like, which is formed by vacuum vapor deposition, is suitably used as the first electrode layer 14 and the second electrode layer 16. Among these, a thin film made of copper, which is formed by vacuum vapor deposition, is particularly suitably used.

Thicknesses of the first electrode layer 14 and the second electrode layer 16 are not limited. In addition, the thicknesses of the first electrode layer 14 and the second electrode layer 16 are basically the same as each other, but may be different from each other.

Here, same as the first protective layer 18 and the second protective layer 20 described above, in a case where the rigidity of the first electrode layer 14 and the second electrode layer 16 is extremely high, not only the stretch and contraction of the piezoelectric layer 12 is constrained, but also the flexibility is impaired. Therefore, it is advantageous that the thicknesses of the first electrode layer 14 and the second electrode layer 16 decrease in a case where electric resistance is not extremely high.

In the piezoelectric film 10, from the viewpoint that the flexibility is not considerably impaired, it is suitable that a product of the thickness and the Young's modulus of the first electrode layer 14 and the second electrode layer 16 is less than a product of the thickness and the Young's modulus of the first protective layer 18 and the second protective layer 20.

As an example, a case of a combination consisting of the first protective layer 18 and the second protective layer 20, which are formed of PET, and the first electrode layer 14 and the second electrode layer 16, which are formed of copper, is exemplified. In the combination, a Young's modulus of PET is approximately 6.2 GPa, and a Young's modulus of copper is approximately 130 GPa. Therefore, in a case where the thickness of the first protective layer 18 and the second protective layer 20 is set to 10 μm, the thickness of the first electrode layer 14 and the second electrode layer 16 is preferably 0.5 μm or less, more preferably 0.3 μm or less, and still more preferably 0.1 μm or less.

On the other hand, from the viewpoint that the cracking and breakage of the electrode layer can be suitably prevented, and for example, a high sound pressure can be output in a case where the piezoelectric film 10 is used as a piezoelectric speaker, the thickness of the first electrode layer 14 and the second electrode layer 16 is preferably 20 nm or more, more preferably 35 nm or more, and still more preferably 50 nm or more.

In the piezoelectric film 10 according to the embodiment of the present invention, a bonding layer for increasing adhesiveness between the piezoelectric layer 12 and the electrode layer may be provided between the piezoelectric layer 12 and the first electrode layer 14 and/or between the piezoelectric layer 12 and the second electrode layer 16.

The bonding layer is not limited, and a known bonding agent (adhesive or pressure sensitive adhesive) can be used depending on the forming materials of the piezoelectric layer 12 and the electrode layer, as long as it can bond the two. In addition, the polymer material used as the matrix 24 of the piezoelectric layer 12 may be used as the bonding layer.

A thickness of the bonding layer is not limited, and a thickness at which sufficient bonding strength can be obtained may be appropriately set. In addition, in a case where a required bonding strength can be obtained, it is preferable that the bonding layer is thin.

The piezoelectric film 10 according to the embodiment of the present invention includes the first electrode layer 14 on one surface of the piezoelectric layer 12 and the second electrode layer 16 on the other surface thereof. In addition, the piezoelectric film 10 of the illustrated example includes the first protective layer 18 covering the first electrode layer 14 and the second protective layer 20 covering the second electrode layer 16.

Furthermore, in the piezoelectric film 10 according to the embodiment of the present invention, the piezoelectric layer 12 is a polymer-based piezoelectric composite material which is formed by dispersing the piezoelectric particles 26 in the matrix 24 containing the polymer material.

Here, in the piezoelectric film 10 according to the embodiment of the present invention, the ratio of the elastic recovery amount of the piezoelectric layer 12 and the protective layer (the first protective layer 18 and the second protective layer 20) by a nanoindentation measurement is in a range of 0.27 to 1.19.

Specifically, in the piezoelectric film 10 according to the embodiment of the present invention, in a case where a ratio D between an elastic recovery amount of the piezoelectric layer 12 and an elastic recovery amount of the protective layer, which are obtained by a nanoindentation measurement, is determined as “ratio D of elastic recovery amount=(elastic recovery amount of piezoelectric layer/elastic recovery amount of protective layer)”, the ratio D of the elastic recovery amount satisfies “0.27≤D≤1.19”.

More specifically, in the present invention, as conceptually shown in FIG. 2, using a nanotriboindenter TI950 manufactured by Bruker and Berkovich indenter made of diamond as an indenter, the nanoindentation measurement of the piezoelectric layer 12 is performed under conditions of the maximum load of 200 μN, a load time of 10 sec, the maximum load holding time of 10 sec, and a release time of 10 sec.

In the piezoelectric film 10 according to the embodiment of the present invention, the ratio D of the elastic recovery amount between the piezoelectric layer 12 and the protective layer by the nanoindentation measurement satisfies “0.27≤D≤1.19”.

Since the piezoelectric film 10 according to the embodiment of the present invention has such a configuration, the interlayer peeling between the first electrode layer 14 and the piezoelectric layer 12 and between the second electrode layer 16 and the piezoelectric layer 12 is significantly reduced, and further, the cracking and breakage of the first electrode layer 14 and the second electrode layer 16 can also be significantly reduced.

As an example, as will be described later, the piezoelectric film 10 including the electrode layers on both surfaces of the piezoelectric layer 12 and the protective layers covering the electrode layers is produced as follows.

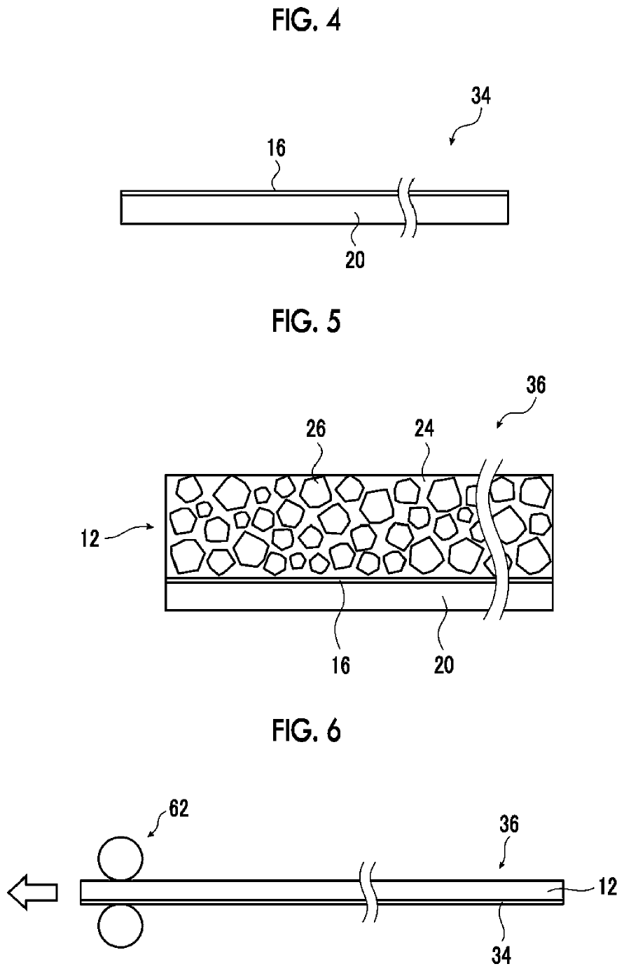

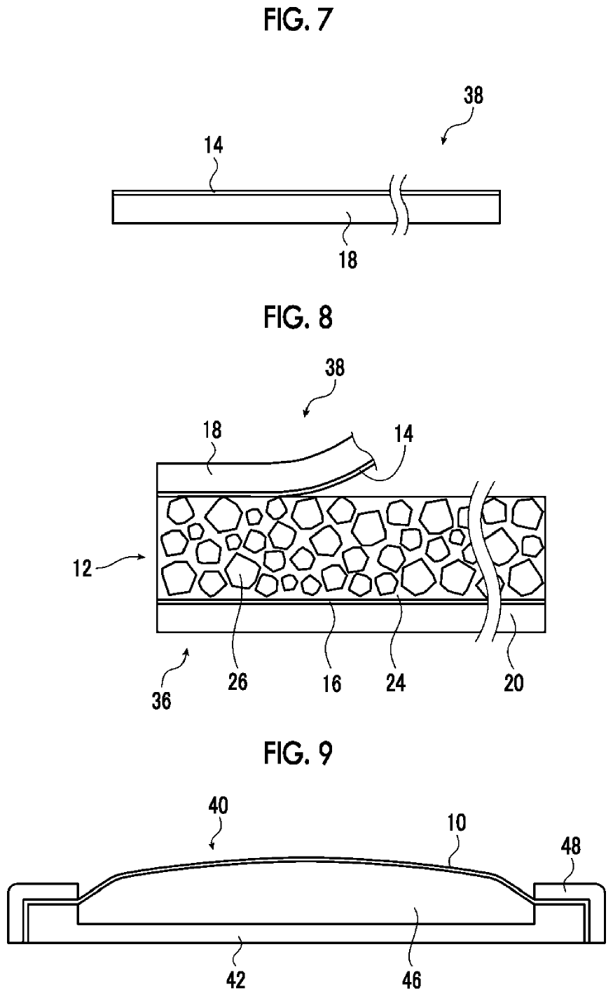

A sheet-like material 34 in which the second protective layer 20 and the second electrode layer 16 are laminated, and a sheet-like material 38 in which the first protective layer 18 and the first electrode layer 14 are laminated are prepared (see FIG. 4 and FIG. 7). On the other hand, materials to be the matrix 24 are dissolved in a solvent, and the piezoelectric particles 26 are dispersed in the solution to prepare a coating material.

The coating material is applied onto the second electrode layer 16 of the sheet-like material 34, and dried to form the piezoelectric layer 12 (see FIG. 5). In this manner, a piezoelectric multilayer body 36 in which the second electrode layer 16 is provided on the second protective layer 20 and the piezoelectric layer 12 is provided on the second electrode layer 16 is produced.

Next, a calender treatment, polarization, and the like are performed as necessary.

Thereafter, the sheet-like material 38 in which the first protective layer 18 and the first electrode layer 14 are laminated is laminated on the piezoelectric layer 12 such that the first electrode layer 14 faces the piezoelectric layer 12, and the laminate is subjected to thermal compression bonding of heating and pressurizing the laminate to produce the piezoelectric film 10 (see FIG. 8).

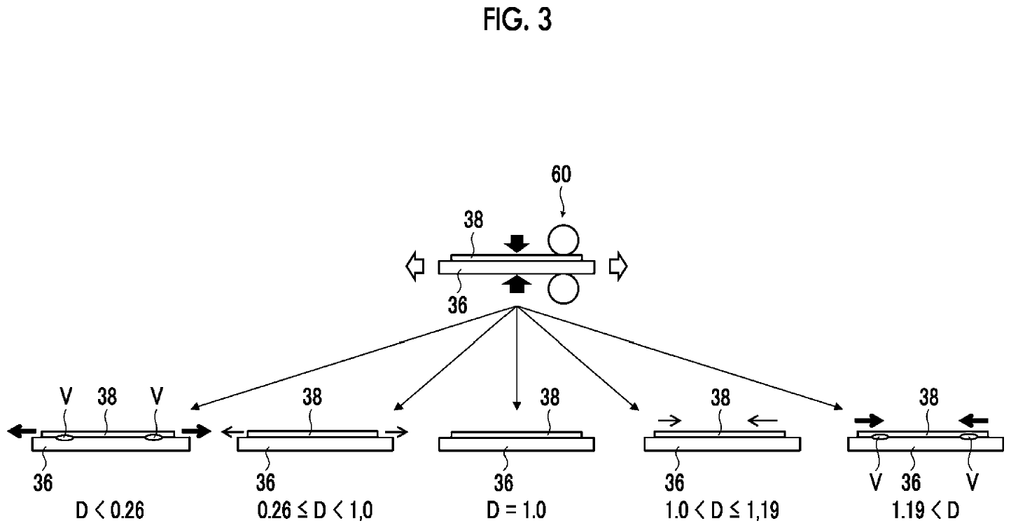

As an example, as conceptually shown in FIG. 3, the bonding of the piezoelectric layer 12 and the first electrode layer 14 is performed by thermal compression bonding using a heating roller pair 60.

Specifically, as described above, the piezoelectric multilayer body 36 in which the piezoelectric layer 12 is formed on the second electrode layer 16 of the sheet-like material 34 is produced (see FIG. 5), and then the sheet-like material 38 is laminated on the piezoelectric multilayer body 36 such that the first electrode layer 14 faces the piezoelectric layer 12 (see FIG. 8).

By sandwiching and transporting the laminate of the piezoelectric multilayer body 36 and the sheet-like material 38 with the heating roller pair 60, the piezoelectric layer 12 and the first electrode layer 14 are subjected to the thermal compression bonding to be bonded. The thermal compression bonding is usually performed by sandwiching and transporting the laminate with the heating roller pair 60, but conversely, the laminate may be fixed and then the heating roller pair 60 may be moved.

Here, both the piezoelectric layer 12 and the protective layer (the first protective layer 18 and the second protective layer 20) in which the resin film is suitably used are an elastic body.

Therefore, as conceptually shown in the upper part of FIG. 3, by the thermal compression bonding of the laminate of the piezoelectric multilayer body 36 and the sheet-like material 38, the piezoelectric layer 12 and the protective layer are both compressed in the thickness direction as shown by black arrows, and accordingly expand in the plane direction as shown by white arrows. In addition, in a case where the laminate of the piezoelectric multilayer body 36 and the sheet-like material 38 is released from the thermal compression bonding, the thicknesses of the piezoelectric layer 12 and the protective layer are returned to their original thicknesses, and as conceptually shown in the lower part of FIG. 3, the piezoelectric layer 12 and the protective layer accordingly contract in the plane direction.

Here, in a case where, in the piezoelectric layer 12 and the protective layer, there is a difference in amount of restoration of the thickness, that is, in amount of contraction in the plane direction, due to this, the piezoelectric layer 12 and the protective layer are partially peeled off with each other, and cracking and breakage occur in the electrode layer (the first electrode layer 14 and the second electrode layer 16).

As described above, for example, in a case where the thickness of the piezoelectric layer 12 is 50 μm, a thickness of the protective layer is preferably 25 μm or less, more preferably 20 μm or less, and still more preferably 10 μm or less. That is, in the piezoelectric film 10, as an example, the piezoelectric layer 12 is much thicker than the protective layer.

In this case, the piezoelectric layer 12 is dominant in the contraction of the piezoelectric layer 12 and the protective layer due to the release of the thermal compression bonding. As described above, since the thickness of the electrode layer is extremely thin as compared with the protective layer, the electrode layer does not affect the contraction of the protective layer and the piezoelectric layer 12.

In this case, for example, in a case where the amount of contraction of the piezoelectric layer 12 is smaller than that of the protective layer, the protective layer tends to contract more than the piezoelectric layer. However, the contraction of the protective layer is hindered by the piezoelectric layer 12 which controls the contraction. Therefore, the protective layer cannot be contracted according to the physical properties, and is in a stretched state in the plane direction. As a result, stress is applied to the protective layer, and partial interlayer peeling occurs between the piezoelectric layer 12 and the protective layer (see the left side of the lower part of FIG. 3). In addition, since the protective layer is in a stretched state, cracking and breakage occur in the electrode layer bonded to the protective layer.

On the contrary, in a case where the amount of contraction of the piezoelectric layer 12 is larger than that of the protective layer, the amount of contraction of the protective layer is smaller than that of the piezoelectric layer 12. As described above, the contraction of the piezoelectric layer 12 and the protective layer is controlled by the piezoelectric layer 12. Therefore, due to the contraction of the piezoelectric layer 12, the protective layer is in a state of being more greatly contracted than contraction corresponding to the physical properties of the protective layer, and is in a state of being compressed and contracted in the plane direction. As a result, similarly, stress is applied to the protective layer, and partial interlayer peeling occurs between the piezoelectric layer 12 and the protective layer (see the right side of the lower part of FIG. 3).

Here, in a case where the thermal compression bonding is released after the thermal compression bonding is performed, the contraction of the piezoelectric layer 12 and the protective layer corresponds to the elastic recovery amount by the nanoindentation measurement. That is, in a case where the thermal compression bonding is released after the thermal compression bonding is performed, the contraction of the piezoelectric layer 12 and the protective layer follows the amount of displacement from the maximum indentation amount after the maximum load is removed in the nanoindentation measurement.

In the piezoelectric film 10 according to the embodiment of the present invention, in a case where a ratio D between an elastic recovery amount of the piezoelectric layer 12 and an elastic recovery amount of the protective layer, which are obtained by a nanoindentation measurement, is determined as “ratio D of elastic recovery amount=(elastic recovery amount of piezoelectric layer/elastic recovery amount of protective layer)”, the ratio D of the elastic recovery amount satisfies “0.27≤D≤1.19”. That is, in the piezoelectric film 10 according to the embodiment of the present invention, the ratio D of the elastic recovery amount between the piezoelectric layer 12 and the protective layer by the nanoindentation measurement is in a range of 0.27 to 1.19.

In the following description, the “ratio D of the elastic recovery amount between the piezoelectric layer and the protective layer by the nanoindentation measurement” is also simply referred to as “ratio D of the elastic recovery amount”.

Since the piezoelectric film 10 according to the embodiment of the present invention has such a configuration, the interlayer peeling between the piezoelectric layer 12 and the electrode layer can be significantly reduced. In addition, the cracking and breakage of the electrode layer can be significantly reduced.

That is, as shown in the center of the lower part of FIG. 3, in a case where the ratio D of the elastic recovery amount is 1 (D=1.0), the amount of contraction of the piezoelectric layer 12 (piezoelectric multilayer body 36) and the amount of contraction of the protective layer (sheet-like material 38) after the thermal compression bonding is released is approximately equal. Therefore, in this case, since no stress is applied to the protective layer, the interlayer peeling between the piezoelectric layer 12 and the protective layer does not occur, and the cracking and breakage do not occur in the electrode layer.

In a case where the elastic recovery amount of the piezoelectric layer 12 is smaller than that of the protective layer, that is, in a case where the ratio D of the elastic recovery amount is less than 1 (D<1.0), that is, the amount of contraction of the piezoelectric layer 12 is smaller than that of the protective layer, as described above, the protective layer is in a state of being stretched in the plane direction. However, even in this case, in a case where the ratio D of the elastic recovery amount is 0.26 or more (0.26≤D), as shown by thin arrows from the second left side in the lower part of FIG. 3, tension applied to the protective layer is small. Therefore, the interlayer peeling occurring between the piezoelectric layer 12 and the protective layer can be extremely reduced, and even in a case where the cracking and breakage occur in the electrode layer, the cracking and breakage can be made to a level at which no problem occurs in practical use.

In a case where the elastic recovery amount of the piezoelectric layer 12 is larger than that of the protective layer, that is, in a case where the ratio D of the elastic recovery amount is more than 1 (1.0<D), that is, the amount of contraction of the piezoelectric layer 12 is larger than that of the protective layer, as described above, the protective layer is in a state of being compressed in the plane direction. However, even in this case, in a case where the ratio D of the elastic recovery amount is 1.19 or less (D≤1.19), as shown by thin arrows from the second right side in the lower part of FIG. 3, compressive force in the plane direction related to the protective layer is small. Therefore, the interlayer peeling between the piezoelectric layer 12 and the protective layer does not occur, and the cracking and breakage do not occur in the electrode layer.

Accordingly, the piezoelectric film 10 according to the embodiment of the present invention can efficiently vibrate the piezoelectric layer 12 and efficiently transmit the vibration of the piezoelectric layer 12, and can output a sound with a high sound pressure in a case of being used as, for example, a piezoelectric speaker.

On the contrary, in a case where the elastic recovery amount of the piezoelectric layer 12 is smaller than that of the protective layer and the ratio D of the elastic recovery amount is less than 0.26 (D<0.26), as shown by thick arrows on the left side of the lower part of FIG. 3, the protective layer is in a state of being strongly stretched in the plane direction. As a result, strong stress is applied to the protective layer, and as shown in the left side of the lower part of FIG. 3, a large number of interlayer peelings V (voids) occur between the piezoelectric layer 12 and the protective layer. In addition, since the protective layer is in a state of being strongly stretched in the plane direction, cracking and breakage occur in the electrode layer bonded to the protective layer, which is a problem in practical use.

In addition, in a case where the elastic recovery amount of the piezoelectric layer 12 is larger than that of the protective layer and the ratio D of the elastic recovery amount is more than 1.19 (1.19<D), as shown by thick arrows on the right side of the lower part of FIG. 3, the protective layer is in a state of being strongly compressed in the plane direction. As a result, strong stress is applied to the protective layer, and as shown in the right side of the lower part of FIG. 3, a large number of interlayer peelings V (voids) occur between the piezoelectric layer 12 and the protective layer.

As a result, for example, in a case of being used as a piezoelectric speaker, a sufficient sound pressure may not be obtained.

The ratio D of the elastic recovery amount is preferably 0.35 to 1.19 and more preferably 0.38 to 1.13.

Particularly, in a case where the ratio D of the elastic recovery amount is 0.35 or more, the occurrence of cracking and breakage in the electrode layer can be more suitably prevented, and the interlayer peeling between the piezoelectric layer 12 and the protective layer can also be prevented. Furthermore, in a case where the thickness of the electrode layer is 20 nm or more as described above, it is possible to more suitably prevent the occurrence of cracking and breakage in the electrode layer.

The nanoindentation measurement of the piezoelectric layer 12 is performed by removing the protective layers and the electrode layers from the piezoelectric film 10 to expose the piezoelectric layer 12.

A method of removing the protective layers and the electrode layers from the piezoelectric film 10 is not limited, and the following method is exemplified as an example.

First, a 5 mol/liter (L) NaOH aqueous solution with a liquid temperature of 15° C. to 25° C. is dropped to the protective layers of the piezoelectric film 10 and allowed to stand to dissolve to the protective layers, thereby exposing the electrode layers. In this case, the electrode layers may be partially dissolved, but the standing time is set such that the NaOH aqueous solution does not come into contact with the piezoelectric layer 12.

After the dropping of the NaOH aqueous solution, the piezoelectric film 10 is allowed to stand for a predetermined time to expose the electrode layer, and then washed with pure water. After the washing, the exposed electrode layer is dissolved in a 0.01 mol/L ferric chloride aqueous solution. The dissolution of the electrode layer with the ferric chloride aqueous solution is performed until the piezoelectric layer 12 is exposed in an area required for the nanoindentation measurement, and the dissolution time does not exceed 5 minutes after the piezoelectric layer 12 is exposed.

After the dissolution of the electrode layer is completed, the piezoelectric film 10 where the piezoelectric layer 12 is exposed is washed with pure water and dried at 30° C. or lower.

With the piezoelectric layer 12 exposed in this manner, as described above, using the nanotriboindenter TI950 and Berkovich indenter made of diamond, the nanoindentation measurement conceptually shown in FIG. 2 is performed to measure the elastic recovery amount of the piezoelectric layer 12.

In the present invention, the elastic recovery amount of the piezoelectric layer 12 may be measured on either surface (main surface) of the first electrode layer 14 side or the second electrode layer 16 side in the piezoelectric layer 12.

On the other hand, the nanoindentation measurement of the protective layer is performed by removing the piezoelectric layer 12 from the piezoelectric film 10 to expose the protective layer with the electrode layer. In the exposed protective layer, as described above, using the nanotriboindenter TI950 and Berkovich indenter made of diamond, the nanoindentation measurement conceptually shown in FIG. 2 may be performed to measure the elastic recovery amount of the protective layer.

The electrode layer adheres to the sheet-like material, but as described above, since the electrode layer is significantly thinner than the protective layer, the result of the nanoindentation measurement is not affected.

A method of removing the piezoelectric layer from the piezoelectric film 10 is not limited, and the following method is exemplified as an example.

First, in a case where the piezoelectric film 10 is immersed in methyl ethyl ketone (MEK) at normal temperature, since the piezoelectric layer is dissolved after being allowed to stand for approximately 1 week, the protective layer with the electrode layer can be taken out.

For the piezoelectric layer which cannot be partially removed, the taken-out protective layer is wiped off and removed with methyl ethyl ketone, and then dried at normal temperature.

With the protective layer taken out in this manner, as described above, using the nanotriboindenter TI950 and Berkovich indenter made of diamond, the nanoindentation measurement conceptually shown in FIG. 2 is performed to measure the elastic recovery amount of the protective layer.

It is preferable that the measurements of the elastic recovery amounts of the piezoelectric layer 12 and the protective layer are performed on at any selected 30 locations, average values thereof are the elastic recovery amount of the piezoelectric layer 12 and the elastic recovery amount of the protective layer in the piezoelectric film 10 to be measured.

Here, the nanoindentation measurement of the piezoelectric layer 12 may be performed at 30 locations on only one surface of the piezoelectric layer 12 or at 30 locations on both surfaces in total.

In addition, in a case where the forming materials, thicknesses, and the like of the first protective layer 18 and the second protective layer 20 in the piezoelectric film 10 are different from each other, the nanoindentation measurement of the protective layer is performed by carrying out the above-described method for each protective layer.

As described above, the piezoelectric film 10 has a configuration in which the piezoelectric layer 12 containing the piezoelectric particles 26 in the matrix 24 containing the polymer material is sandwiched between the first electrode layer 14 and the second electrode layer 16, and this laminate is sandwiched between the first protective layer 18 and the second protective layer 20.

In the piezoelectric film 10 according to the embodiment of the present invention, it is preferable that the maximal value of the loss tangent (tan δ) at a frequency of 1 Hz according to the dynamic viscoelasticity measurement is present at normal temperature, and it is more preferable that the maximal value at which the loss tangent is 0.1 or more is present at normal temperature.

In this manner, even in a case where the piezoelectric film 10 is subjected to large bending deformation at a relatively slow vibration of less than or equal to a few Hz from the outside, since the strain energy can be effectively diffused to the outside as heat, occurrence of cracks at the interface between the polymer matrix and the piezoelectric particles can be prevented.

In addition, in the piezoelectric film 10 according to the embodiment of the present invention, it is preferable that the storage elastic modulus (E′) at a frequency of 1 Hz according to the dynamic viscoelasticity measurement is 10 to 30 GPa at 0° C. and 1 to 10 GPa at 50° C.

In such a manner, the piezoelectric film 10 may have large frequency dispersion in the storage elastic modulus (E′) at normal temperature. That is, the piezoelectric film 10 can exhibit a behavior of being rigid with respect to the vibration of 20 Hz to 20 kHz and being flexible with respect to the vibration of less than or equal to a few Hz.

In addition, in the piezoelectric film 10 according to the embodiment of the present invention, it is preferable that a product of the thickness and the storage elastic modulus (E′) at a frequency of 1 Hz according to the dynamic viscoelasticity measurement is 1.0×10⁶ to 2.0×10⁶ N/m at 0° C. and 1.0×10¹ to 1.0×10⁶ N/m at 50° C.

In this manner, the piezoelectric film 10 may have moderate rigidity and mechanical strength within a range not impairing the flexibility and the acoustic characteristics.

Furthermore, in the piezoelectric film 10, it is preferable that the loss tangent (Tan δ) at a frequency of 1 kHz at 25° C. is 0.05 or more in a master curve obtained from the dynamic viscoelasticity measurement.

In this manner, the frequency of a speaker including the piezoelectric film 10 is smooth as the frequency characteristic thereof, and thus an amount of a change in acoustic quality in a case where the lowest resonance frequency f₀ is changed according to a change in curvature of the speaker can be decreased.

Furthermore, the piezoelectric film 10 according to the embodiment of the present invention may further include an electrode lead-out portion which leads out the electrodes from the first electrode layer 14 and the second electrode layer 16, an insulating layer which covers a region where the piezoelectric layer 12 is exposed for preventing a short circuit or the like, or the like in addition to the above-described layers.

A method of leading out electrodes from the first electrode layer 14 and the second electrode layer 16 is not limited, and various known methods can be used.

Examples thereof include a method of providing portions in the electrode layer and the protective layer, which protrude to the outside of the piezoelectric layer 12 in the plane direction, and leading-out electrodes to the outside from these portions, a method of connecting a conductor such as a copper foil to the first electrode layer 14 and the second electrode layer 16 and leading-out the electrodes to the outside, and a method of forming through-holes in the first protective layer 18 and the second protective layer 20 with a laser or the like, filling the through-holes with a conductive material, and leading-out electrodes to the outside.

Examples of a suitable method of leading out the electrodes include the method described in JP2014-209724A and the method described in JP2016-015354A.

The number of electrode lead-out portions is not limited to one, and each electrode layer may have two or more electrode lead-out portions. Particularly, in a case of the configuration in which the electrode lead-out portion is obtained by removing a part of the protective layer and inserting a conductive material into the hole portion, it is preferable that the electrode layer has three or more electrode lead-out portions in order to more reliably ensure the conduction.

Next, an example of the method of manufacturing the piezoelectric film 10 shown in FIG. 1 will be described with reference to the conceptual views of FIGS. 4 to 8.

First, as shown in FIG. 4, a sheet-like material 34 in which the second electrode layer 16 has been formed on the second protective layer 20 is prepared. The sheet-like material 34 may be produced by forming a copper thin film or the like as the second electrode layer 16 on the surface of the second protective layer 20 using vacuum vapor deposition, sputtering, plating, or the like.

In a case where the second protective layer 20 is extremely thin and thus the handleability is degraded, the second protective layer 20 with a separator (temporary support) may be used as necessary. PET having a thickness of 25 to 100 μm, or the like can be used as the separator. The separator may be removed after thermal compression bonding of the second electrode layer 16 and the second protective layer 20 and before lamination of any member on the second protective layer 20.

Meanwhile, the coating material is prepared by dissolving a polymer material having viscoelasticity at normal temperature, such as cyanoethylated PVA, in an organic solvent, adding the piezoelectric particles 26 thereto, and stirring the solution for dispersion.

The organic solvent is not limited, and various organic solvents such as dimethylformamide (DMF), methyl ethyl ketone, and cyclohexanone can be used.

In a case where the sheet-like material 34 is prepared and the coating material is prepared, the coating material is cast (applied) onto the second electrode layer 16 of the sheet-like material 34, and the organic solvent is evaporated and dried. In this manner, as shown in FIG. 5, the piezoelectric multilayer body 36 in which the second electrode layer 16 is provided on the second protective layer 20 and the piezoelectric layer 12 is formed on the second electrode layer 16 is produced.

A casting method for the coating material is not particularly limited, and all known coating methods (coating devices) such as a slide coater and a doctor knife can be used.

In a case where the viscoelastic material is a material that can be heated and melted, such as cyanoethylated PVA, the piezoelectric multilayer body 36 in which the first electrode layer 14 is provided on the first protective layer 18 and the piezoelectric layer 12 is formed on the first electrode layer 14 as shown in FIG. 5 may be produced by heating and melting the viscoelastic material to produce a melt obtained by adding the piezoelectric particles 26 to the melt to be dispersed therein, extruding the melt on the sheet-like material 34 shown in FIG. 4 in a sheet shape by carrying out extrusion molding or the like, and cooling the laminate.

As described above, in the piezoelectric film 10, in addition to the viscoelastic material such as cyanoethylated PVA, a dielectric polymer material such as polyvinylidene fluoride may be added to the matrix 24.

In a case where the polymer piezoelectric material is added to the matrix 24, the polymer piezoelectric material to be added to the above-described coating material may be dissolved. Alternatively, the polymer piezoelectric material to be added may be added to the heated and melted viscoelastic material described above so that the polymer piezoelectric material is heated and melted.

After the production of the piezoelectric multilayer body 36, it is preferable that the surface of the piezoelectric layer 12 is subjected to a calender treatment of pressing the surface using a heating roller or the like for the purpose of flattening the surface of the piezoelectric layer 12, adjusting the thickness of the piezoelectric layer 12, improving the density of the piezoelectric particles 26 in the piezoelectric layer 12, and the like.

A method of performing the calender treatment is not limited, and the calender treatment may be performed by a known method such as sandwiching and transportation with a heating roller pair, pressing with a heating roller, and treatment with a heated press machine.

Here, as an example, the elastic recovery amount of the piezoelectric layer 12 in the produced piezoelectric film 10 by the nanoindentation measurement can be controlled by adjusting conditions of the calender treatment. In the piezoelectric film 10 according to the embodiment of the present invention, as an example, the ratio D of the elastic recovery amount between the piezoelectric layer 12 and the protective layer may be controlled by controlling the elastic recovery amount of the piezoelectric layer 12.

Specifically, by keeping other conditions constant and adjusting a pressure of the calender treatment, the elastic recovery amount of the piezoelectric layer 12 in the produced piezoelectric film 10 by the nanoindentation measurement can be suitably controlled with favorable controllability.

In the calender treatment, as an example conceptually shown in FIG. 6, the piezoelectric multilayer body 36 in which the piezoelectric layer 12 is formed on the second electrode layer 16 of the sheet-like material 34 is sandwiched and transported between a heating roller pair 62 while being heated and pressed. Alternatively, the piezoelectric multilayer body 36 may be held at a predetermined position, and the heating roller pair 62 may be moved.

In this case, by keeping other conditions constant and adjusting a pressure of the calender treatment, that is, a nip pressure (sandwiching pressure) of the piezoelectric multilayer body 36 by the heating roller pair 62, the elastic recovery amount of the piezoelectric layer 12 by the nanoindentation measurement can be suitably controlled with favorable controllability.

Specifically, the elastic recovery amount of the piezoelectric layer 12 by the nanoindentation measurement can be decreased by increasing the nip pressure of the heating roller pair 62, that is, the pressure of the calender treatment. On the contrary, the elastic recovery amount of the piezoelectric layer 12 by the nanoindentation measurement can be increased by decreasing the nip pressure of the heating roller pair 62, that is, the pressure of the calender treatment.

In the piezoelectric film 10 according to the embodiment of the present invention, the elastic recovery amount of the piezoelectric layer 12 can be controlled by various methods other than adjusting the pressure in the calender treatment. For example, the elastic recovery amount of the piezoelectric layer 12 by the nanoindentation measurement may be controlled by adjusting composition of the matrix 24 in the piezoelectric layer 12.

In addition, in the present invention, the control of the ratio D of the elastic recovery amount between the piezoelectric layer 12 and the protective layer is not limited to the control of the elastic recovery amount of the piezoelectric layer 12. For example, by adjusting the forming material of the protective layer, the thickness of the protective layer, and the like, the elastic recovery amount of the protective layer by the nanoindentation measurement may be controlled to control the ratio D of the elastic recovery amount.

Furthermore, the ratio D of the elastic recovery amount may be controlled by controlling both the elastic recovery amount of the piezoelectric layer 12 by the nanoindentation measurement and the elastic recovery amount of the protective layer by the nanoindentation measurement.

The calender treatment may be performed after a polarization treatment described later. However, in a case where the calender treatment is performed after the polarization treatment is performed, the piezoelectric particles 26 pushed in by the pressure rotate, which may decrease effect of the polarization treatment. In consideration of this point, it is preferable that the calender treatment is performed before the polarization treatment.

After the production of the piezoelectric multilayer body 36 in which the second electrode layer 16 is provided on the second protective layer 20 and the piezoelectric layer 12 is formed on the second electrode layer 16, it is preferable that a polarization treatment (poling) is performed on the piezoelectric layer 12 after the calender treatment is performed on the piezoelectric layer 12.

A method of performing the polarization treatment on the piezoelectric layer 12 is not limited, and a known method can be used. For example, electric field poling in which a DC electric field is directly applied to a target to be subjected to the polarization treatment is exemplified. In a case of performing the electric field poling, the electric field poling treatment may be performed using the first electrode layer 14 and the second electrode layer 16 by forming the first electrode layer 14 before the polarization treatment.

In addition, in a case where the piezoelectric film 10 according to the embodiment of the present invention is produced, it is preferable that the polarization treatment is performed in the thickness direction instead of the plane direction of the piezoelectric layer 12.

On the other hand, as shown in FIG. 7, the sheet-like material 38 in which the first electrode layer 14 has been formed on the first protective layer 18 is prepared. The sheet-like material 38 may be produced by forming a copper thin film or the like as the first electrode layer 14 on the surface of the first protective layer 18 using vacuum vapor deposition, sputtering, plating, or the like. That is, the sheet-like material 38 may be the same as the sheet-like material 34 described above.

Next, as shown in FIG. 8, the sheet-like material 38 is laminated on the piezoelectric multilayer body 36 such that the first electrode layer 14 faces the piezoelectric layer 12.

Furthermore, as shown in FIG. 3 described above, the piezoelectric film 10 is produced by sandwiching and transporting the laminate of the piezoelectric multilayer body 36 and the sheet-like material 38 with the heating roller pair 60 while performing thermal compression bonding. Alternatively, the piezoelectric film 10 may be produced by performing the thermal compression bonding on the laminate of the piezoelectric multilayer body 36 and the sheet-like material 38 using a heating press device.

The piezoelectric film 10 to be produced in the above-described manner is polarized in the thickness direction instead of the plane direction, and thus excellent piezoelectric characteristics are obtained even in a case where a stretching treatment is not performed after the polarization treatment. Therefore, the piezoelectric film 10 has no in-plane anisotropy as a piezoelectric characteristic, and stretches and contracts isotropically in all directions in the plane direction in a case where a driving voltage is applied.

Such a piezoelectric film 10 may be produced using the cut sheet-like material 34 and the cut sheet-like material 38, or may be produced using Roll to Roll.

FIG. 9 conceptually shows an example of a flat plate type piezoelectric speaker including the piezoelectric film 10 according to the embodiment of the present invention.

A piezoelectric speaker 40 is a flat plate type piezoelectric speaker which uses the piezoelectric film 10 as a vibration plate converting an electrical signal into vibration energy. The piezoelectric speaker 40 can also be used as a microphone, a sensor, or the like. Furthermore, the piezoelectric speaker can also be used as a vibration sensor.

The piezoelectric speaker 40 is configured to include the piezoelectric film 10, a case 42, a viscoelastic support 46, and a frame 48.

The case 42 is a thin housing which is formed of plastic or the like and has one opening surface. Examples of a shape of the housing include a rectangular parallelepiped shape, a cubic shape, and a cylindrical shape.

In addition, the frame 48 is a frame material which has, in the center thereof, a through-hole having the same shape as the opening surface of the case 42 and engages with the opening surface side of the case 42.

The viscoelastic support 46 is a support used for efficiently converting the stretch and contraction movement of the piezoelectric film 10 into a forward and rearward movement by means of having appropriate viscosity and elasticity, supporting the piezoelectric film 10, and applying a constant mechanical bias to any place of the piezoelectric film. The forward and rearward movement of the piezoelectric film 10 is a movement in a direction perpendicular to the surface of the film.

Examples of the viscoelastic support 46 include nonwoven fabric such as wool felt and wool felt containing PET, and glass wool.

The piezoelectric speaker 40 is configured by accommodating the viscoelastic support 46 in the case 42, covering the case 42 and the viscoelastic support 46 with the piezoelectric film 10, and fixing the frame 48 to the case 42 in a state of pressing a periphery of the piezoelectric film 10 against an upper end surface of the case 42 by the frame 48.

Here, in the piezoelectric speaker 40, the viscoelastic support 46 has a shape in which a height (thickness) thereof is larger than a height of an inner surface of the case 42.

Therefore, in the piezoelectric speaker 40, the viscoelastic support 46 is held in a state of being thinned by being pressed downward by the piezoelectric film 10 at the peripheral portion of the viscoelastic support 46. In addition, in the peripheral portion of the viscoelastic support 46, a curvature of the piezoelectric film 10 suddenly fluctuates, and a rising portion which decreases in height toward the periphery of the viscoelastic support 46 is formed in the piezoelectric film 10. Furthermore, a central region of the piezoelectric film 10 is pressed by the viscoelastic support 46 having a square columnar shape, and has a (approximately) planar shape.

In the piezoelectric speaker 40, in a case where the piezoelectric film 10 stretches in the plane direction due to the application of the driving voltage to the first electrode layer 14 and the second electrode layer 16, the rising portion of the piezoelectric film 10 changes an angle in a rising direction due to the action of the viscoelastic support 46 in order to absorb the stretched part. As a result, the piezoelectric film 10 having the planar portion moves upward.

On the contrary, in a case where the piezoelectric film 10 contracts in the plane direction due to the application of the driving voltage to the second electrode layer 16 and the first electrode layer 14, the rising portion of the piezoelectric film 10 changes an angle in a falling direction (a direction approaching the flat surface) in order to absorb the contracted part. As a result, the piezoelectric film 10 having the planar portion moves downward.

The piezoelectric speaker 40 generates a sound by the vibration of the piezoelectric film 10.

In the piezoelectric film 10 according to the embodiment of the present invention, the conversion from the stretching and contracting movement to the vibration can also be achieved by holding the piezoelectric film 10 in a bent state.

Therefore, as shown in FIG. 9, the piezoelectric film 10 according to the embodiment of the present invention can function as a piezoelectric speaker having flexibility, a vibration sensor, or the like by being simply maintained in a bent state instead of the flat plate-like piezoelectric speaker 40 having rigidity.

Such a piezoelectric speaker including the piezoelectric film 10 can be accommodated in a bag or the like by, for example, being rolled or folded using the favorable flexibility. Therefore, with the piezoelectric film 10, a piezoelectric speaker which can be easily carried even in a case where the piezoelectric speaker has a certain size can be realized.

In addition, as described above, the piezoelectric film 10 has excellent elasticity and excellent flexibility, and has no in-plane anisotropy as a piezoelectric characteristic. Therefore, in the piezoelectric film 10, a change in acoustic quality is small regardless of the direction in which the film is bent, and a change in acoustic quality with respect to the change in curvature is also small. Accordingly, the piezoelectric speaker including the piezoelectric film 10 has a high degree of freedom of the installation place, and can be attached to various articles as described above. For example, a so-called wearable speaker can be realized by attaching the piezoelectric film 10 to clothes such as a suit and portable items such as a bag in a bent state.

Furthermore, as described above, the piezoelectric film according to the embodiment of the present invention can be used as a speaker of a display device by bonding the piezoelectric film to a display device having flexibility, such as an organic electroluminescence display having flexibility and a liquid crystal display having flexibility.

As described above, since the piezoelectric film 10 stretches and contracts in the plane direction in a case where a voltage is applied, and vibrates suitably in the thickness direction due to the stretch and contraction in the plane direction, a favorable acoustic characteristic of outputting a sound with a high sound pressure is exhibited, for example, in a case where the piezoelectric film is used for a piezoelectric speaker or the like.

The piezoelectric film 10, which exhibits favorable acoustic characteristics, that is, high stretch and contraction performance due to piezoelectricity satisfactorily acts as a piezoelectric vibrating element which vibrates a vibration body such as a vibration plate by laminating a plurality of layers of the piezoelectric films to obtain a laminated piezoelectric element.

In a case of lamination of the piezoelectric films 10, each piezoelectric film may not have the first protective layer 18 and/or the second protective layer 20 unless there is a possibility of a short circuit. Alternatively, the piezoelectric films which do not have the first protective layer 18 and/or the second protective layer 20 may be laminated through an insulating layer.

As an example, the laminated piezoelectric element obtained by laminating the piezoelectric films 10 is bonded to a vibration plate and may be used as a speaker which outputs a sound by vibrating the vibration plate using the laminate of the piezoelectric films 10. That is, in this case, the laminated piezoelectric element obtained by laminating the piezoelectric films 10 acts as a so-called exciter which outputs a sound by vibrating the vibration plate.

By applying a driving voltage to the laminated piezoelectric element obtained by laminating the piezoelectric films 10, each of the piezoelectric films 10 stretches and contracts in the plane direction, and the entire laminate of the piezoelectric films 10 stretches and contracts in the plane direction due to the stretch and contraction of each of the piezoelectric films 10. The vibration plate to which the laminate has been bonded is bent due to the stretch and contraction of the laminated piezoelectric element in the plane direction, and as a result, the vibration plate vibrates in the thickness direction. The vibration plate generates a sound using the vibration in the thickness direction. The vibration plate vibrates according to the magnitude of the driving voltage applied to the piezoelectric film 10 and generates the sound according to the driving voltage applied to the piezoelectric film 10.

Therefore, the piezoelectric film 10 itself does not output a sound in this case.

Therefore, even in a case where the rigidity of each piezoelectric film 10 is low and the stretching and contracting force thereof is small, the rigidity of the laminated piezoelectric element obtained by laminating the piezoelectric films 10 is increased, and the stretching and contracting force as the entire laminate is increased. As a result, in the laminated piezoelectric element obtained by laminating the piezoelectric films 10, even in a case where the vibration plate has a certain degree of rigidity, the vibration plate is sufficiently bent with a large force and can be sufficiently vibrated in the thickness direction, and thus the vibration plate can generate a sound.

In the laminated piezoelectric element obtained by laminating the piezoelectric films 10, the number of laminated piezoelectric films 10 is not limited, and the number of sheets providing a sufficient amount of vibration may be appropriately set according to, for example, the rigidity of the vibration plate to be vibrated.

One piezoelectric film 10 can also be used as a similar exciter (piezoelectric vibrating element) in a case where one piezoelectric film has a sufficient stretching and contracting force.

The vibration plate which is vibrated by the laminated piezoelectric element obtained by laminating the piezoelectric films 10 is not limited, and various sheet-like materials (plate-like materials and films) can be used.

Examples thereof include a resin film consisting of polyethylene terephthalate (PET) and the like, foamed plastic consisting of foamed polystyrene and the like, a paper material such as a corrugated cardboard material, a glass plate, and wood. Furthermore, various machines (devices) such as display devices such as an organic electroluminescence display and a liquid crystal display may be used as the vibration plate as long as the devices can be sufficiently bent.

It is preferable that the laminated piezoelectric element obtained by laminating the piezoelectric films 10 is formed by bonding adjacent piezoelectric films 10 with a bonding layer (bonding agent). Further, it is preferable that the laminated piezoelectric element and the vibration plate are also bonded with a bonding layer.

The bonding layer is not limited, and various layers which can bond materials to be bonded can be used. Therefore, the bonding layer may consist of a pressure sensitive adhesive or an adhesive. From the viewpoint that a solid and hard bonding layer is obtained after the bonding, it is preferable to use an adhesive layer consisting of an adhesive.

Regarding the above points, the same applies to a laminate formed by folding a long piezoelectric film 10, which will be described later.

In the laminated piezoelectric element obtained by laminating the piezoelectric films 10, a polarization direction of each piezoelectric film 10 to be laminated is not limited. As described above, it is preferable that the piezoelectric film 10 according to the embodiment of the present invention is polarized in the thickness direction. Accordingly, the polarization direction of the piezoelectric film 10 here is a polarization direction in the thickness direction.

Therefore, in the laminated piezoelectric element, the polarization directions may be the same for all the piezoelectric films 10, and piezoelectric films having different polarization directions may be present.

In a laminated piezoelectric element obtained by laminating the piezoelectric films 10, it is preferable that the piezoelectric films 10 are laminated such that the adjacent piezoelectric films 10 have polarization directions opposite to each other.

In the piezoelectric film 10, the polarity of the voltage to be applied to the piezoelectric layer 12 depends on the polarization direction of the piezoelectric layer 12. Therefore, even in a case where the polarization direction is directed from the first electrode layer 14 toward the second electrode layer 16 or from the second electrode layer 16 toward the first electrode layer 14, the polarity of the first electrode layer 14 and the polarity of the second electrode layer 16 in all the piezoelectric films 10 to be laminated are set to be the same as each other.

Therefore, even in a case where the electrode layers of the adjacent piezoelectric films 10 come into contact with each other, since the electrode layers in contact with each other have the same polarity by reversing the polarization directions of the adjacent piezoelectric films 10, there is no risk of a short circuit.

The laminated piezoelectric element obtained by laminating the piezoelectric films 10 may have a configuration in which a plurality of piezoelectric films 10 are laminated by folding the piezoelectric film 10 once or more times, preferably a plurality of times.

The configuration in which the piezoelectric film 10 is folded and laminated has the following advantages.

That is, in the laminate in which a plurality of cut sheet-like piezoelectric films 10 are laminated, it is necessary to connect the first electrode layer 14 and the second electrode layer 16 to a driving power supply for each piezoelectric film. On the contrary, in the configuration in which the long piezoelectric film 10 is folded and laminated, only one sheet of the long piezoelectric film 10 can form the laminated piezoelectric element. Therefore, in the configuration in which the long piezoelectric film 10 is folded and laminated, only one power supply is required for applying the driving voltage, and the electrodes may be led out from the piezoelectric film 10 at one place.

Furthermore, in the configuration in which the long piezoelectric film 10 is folded and laminated, polarization directions of adjacent piezoelectric films 10 are inevitably opposite to each other.

Such a laminated piezoelectric element obtained by providing electrode layers on both surfaces of a piezoelectric layer consisting of a polymer-based piezoelectric composite material and preferably by laminating piezoelectric films in which a protective layer is provided on the surface of an electrode layer is described in WO2020/095812A and WO2020/179353A.

The piezoelectric film and the laminated piezoelectric element according to the embodiment of the present invention are suitably used for various applications, such as various sensors, acoustic devices, haptics, ultrasonic transducers, actuators, damping materials (dampers), and vibration power generators.

Specifically, examples of the sensor including the piezoelectric film and the laminated piezoelectric element according to the embodiment of the present invention include sound wave sensors, ultrasound wave sensors, pressure sensors, tactile sensors, strain sensors, and vibration sensors. The sensor including the piezoelectric film and the laminated piezoelectric element according to the embodiment of the present invention are particularly useful for infrastructure inspection such as crack detection and examination at a manufacturing site such as foreign matter contamination detection.

Examples of the acoustic device including the piezoelectric film and the laminated piezoelectric element according to the embodiment of the present invention include microphones, pickups, speakers, and exciters. Examples of specific applications of the acoustic device including the piezoelectric film and the laminated piezoelectric element according to the embodiment of the present invention include noise cancellers used for cars, trains, airplanes, robots, and the like, artificial voice bands, buzzers to prevent pests and beasts from invading, furniture having a voice output function, wallpaper, photos, helmets, goggles, headrests, signage, and robots.

Application examples of the haptic including the piezoelectric film and the laminated piezoelectric element according to the embodiment of the present invention include automobiles, smartphones, smart watches, and game machines.

Examples of the ultrasonic transducer including the piezoelectric film and the laminated piezoelectric element according to the embodiment of the present invention include ultrasound probes and hydrophones.

Examples of the applications of the actuator including the piezoelectric film and the laminated piezoelectric element according to the embodiment of the present invention include prevention of attachment of water droplets, transport, stirring, dispersion, and polishing.

Application examples of the damping material including the piezoelectric film and the laminated piezoelectric element according to the embodiment of the present invention include containers, vehicles, buildings, and sports equipment such as skis and rackets.

Furthermore, application examples of the vibration power generator including the piezoelectric film and the laminated piezoelectric element according to the embodiment of the present invention include roads, floors, mattresses, chairs, shoes, tires, wheels, and computer keyboards.

Hereinbefore, the piezoelectric film and the laminated piezoelectric element according to the embodiment of the present invention have been described in detail, but the present invention is not limited to the above-described examples, and various improvements or modifications may be made within a range not departing from the scope of the present invention.

### EXAMPLES

Hereinafter, the present invention will be described in more detail with reference to specific examples of the present invention.

### Example 1

A piezoelectric film shown in FIG. 1 was produced by the methods shown in FIGS. 4 to 8.

First, cyanoethylated PVA (CR-V, manufactured by Shin-Etsu Chemical Co., Ltd.) was dissolved in dimethylformamide (DMF) at the following compositional ratio. Thereafter, PZT particles as piezoelectric particles were added to the solution at the following compositional ratio, and the solution was stirred using a propeller mixer (rotation speed: 2000 rpm), thereby preparing a coating material for forming a piezoelectric layer.
PZT Particles: 300 parts by mass
Cyanoethylated PVA: 30 parts by mass
DMF: 70 parts by mass

PZT particles which were obtained by sintering mixed powder, formed by wet-mixing powder of a Pb oxide, a Zr oxide, and a Ti oxide as main components using a ball mill such that the amount of Zr and the amount of Ti respectively reached 0.52 moles and 0.48 moles with respect to 1 mole of Pb, at 800° C. for 5 hours and being subjected to a crushing treatment were used as the PZT particles.

On the other hand, two sheets of sheet-like materials obtained by performing vacuum vapor deposition on a copper thin film having a thickness of 20 nm were prepared on a PET film having a thickness of 4 μm. That is, in the present example, the first electrode layer and the second electrode layer were copper-deposited thin films having a thickness of 20 nm, and the first protective layer and the second protective layer were PET films having a thickness of 4 μm.

The copper thin film (second electrode layer) of one sheet-like material was coated with the coating material for forming a piezoelectric layer, which was prepared in advance, using a slide coater.

Next, the material obtained by coating the sheet-like material with the coating material was heated and dried on a hot plate at 120° C. to evaporate DMF. In this manner, a piezoelectric multilayer body in which the second electrode layer made of copper was provided on the second protective layer made of PET and the piezoelectric layer (polymer-based piezoelectric composite material layer) having a thickness of 50 μm was formed thereon was produced.

The produced piezoelectric layer (piezoelectric multilayer body) was subjected to a calender treatment using a heating roller pair.

As the heating roller pair, a heating roller having a roll diameter of 300 mm was used, and a pressure (nip pressure) of the calender treatment was set to 280 MPa. A temperature of the heating roller pair was set to 100° C. A transportation speed of the piezoelectric multilayer body was 1 m/min.

After performing the calender treatment, the produced piezoelectric layer was subjected to a polarization treatment in a thickness direction.

The copper thin film (first electrode layer) of the other sheet-like material was laminated on the piezoelectric multilayer body facing the piezoelectric layer.

Next, the laminate of the piezoelectric multilayer body and the sheet-like material was subjected to thermal compression bonding at a temperature of 120° C. using a heating roller pair to adhere the piezoelectric layer and the first electrode layer, thereby producing a piezoelectric film as shown in FIG. 1.

### Example 2

A piezoelectric film was produced in the same manner as in Example 1, except that the pressure (nip pressure) of the calender treatment was set to 180 MPa.

### Example 3

A piezoelectric film was produced in the same manner as in Example 1, except that the pressure (nip pressure) of the calender treatment was set to 158 MPa.

### Example 4

A piezoelectric film was produced in the same manner as in Example 1, except that the pressure (nip pressure) of the calender treatment was set to 130 MPa.

### Example 5

A piezoelectric film was produced in the same manner as in Example 1, except that the pressure (nip pressure) of the calender treatment was set to 100 MPa.

### Example 6

A piezoelectric film was produced in the same manner as in Example 1, except that the pressure (nip pressure) of the calender treatment was set to 73 MPa.

### Example 7

A piezoelectric film was produced in the same manner as in Example 1, except that the pressure (nip pressure) of the calender treatment was set to 70 MPa.

### Example 8

A piezoelectric film was produced in the same manner as in Example 4 (nip pressure: 130 MPa), except that the thickness of the copper thin film serving as the first electrode layer and the second electrode layer was changed from 20 nm to 10 nm.

### Example 9

A piezoelectric film was produced in the same manner as in Example 4 (nip pressure: 130 MPa), except that the thickness of the copper thin film serving as the first electrode layer and the second electrode layer was changed from 20 nm to 35 nm.

### Example 10

A piezoelectric film was produced in the same manner as in Example 4 (nip pressure: 130 MPa), except that the thickness of the copper thin film serving as the first electrode layer and the second electrode layer was changed from 20 nm to 50 nm.

### Comparative Example 1

A piezoelectric film was produced in the same manner as in Example 1, except that the pressure (nip pressure) of the calender treatment was set to 300 MPa.

### Comparative Example 2

A piezoelectric film was produced in the same manner as in Example 1, except that the pressure (nip pressure) of the calender treatment was set to 50 MPa.

[Measurement of Elastic Recovery Amount]

For the produced piezoelectric films, the elastic recovery amounts of the piezoelectric layer and the protective layer were measured as follows.

<Exposure of Piezoelectric Layer>

First, an NaOH aqueous solution having a temperature of 15° C. to 25° C. and a concentration of 5 mol/L was dropped to the first protective layer of the produced piezoelectric film, and allowed to stand for a predetermined time to dissolve the first protective layer, thereby exposing the first electrode layer. In this case, the first electrode layer was partially dissolved, but the standing time was controlled such that the NaOH aqueous solution did not come into contact with the piezoelectric layer.

The piezoelectric film in which the first protective layer was dissolved was washed with pure water. Thereafter, the exposed first electrode layer was dissolved in a 0.01 mol/L ferric chloride aqueous solution. The dissolution of the first electrode layer in the ferric chloride aqueous solution was set to not exceed 5 minutes after the piezoelectric layer was exposed.

The piezoelectric film where the piezoelectric layer 12 was exposed was washed with pure water and dried at 30° C. or lower.

<Taking-Out of Protective Layer>

The produced piezoelectric film was immersed in methyl ethyl ketone at normal temperature, and allowed to stand for 1 week. In this manner, the piezoelectric layer in the piezoelectric film was dissolved, and the protective layer with the electrode layer was taken out.

The taken-out protective layer was further wiped off using methyl ethyl ketone to remove the remaining piezoelectric layer, and was dried at normal temperature.

<Measurement of Elastic Recovery Amount>

For the exposed piezoelectric layer and the taken-out protective layer, using a nanotriboindenter TI950 manufactured by Bruker and Berkovich indenter made of diamond as an indenter, the nanoindentation measurement of the piezoelectric layer was performed under conditions of the maximum load of 200 μN, a load time of 10 sec, the maximum load holding time of 10 sec, and a release time of 10 sec (see FIG. 2) to measure the elastic recovery amount.

The elastic recovery amounts were measured by optionally selecting 30 locations of the exposed piezoelectric layer and 30 locations of the taken-out protective layer, and average values thereof was used as each of the elastic recovery amounts.

[Evaluation]

A sound pressure of the produced piezoelectric film was measured as follows.

<Production of Piezoelectric Speaker and Measurement of Sound Pressure>

The piezoelectric speaker shown in FIG. 9 was produced using the produced piezoelectric film.

First, a rectangular test piece having a size of 210×300 mm (A4 size) was cut out from the produced piezoelectric film. The cut-out piezoelectric film was placed on a 210 x 300 mm case in which glass wool serving as a viscoelastic support was stored in advance as shown in FIG. 9, and the peripheral portion was pressed by a frame to impart an appropriate tension and an appropriate curvature to the piezoelectric film, thereby producing a piezoelectric speaker as shown in FIG. 9.

A depth of the case was set to 9 mm, a density of glass wool was set to 32 kg/m³, and a thickness before assembly was set to 25 mm.

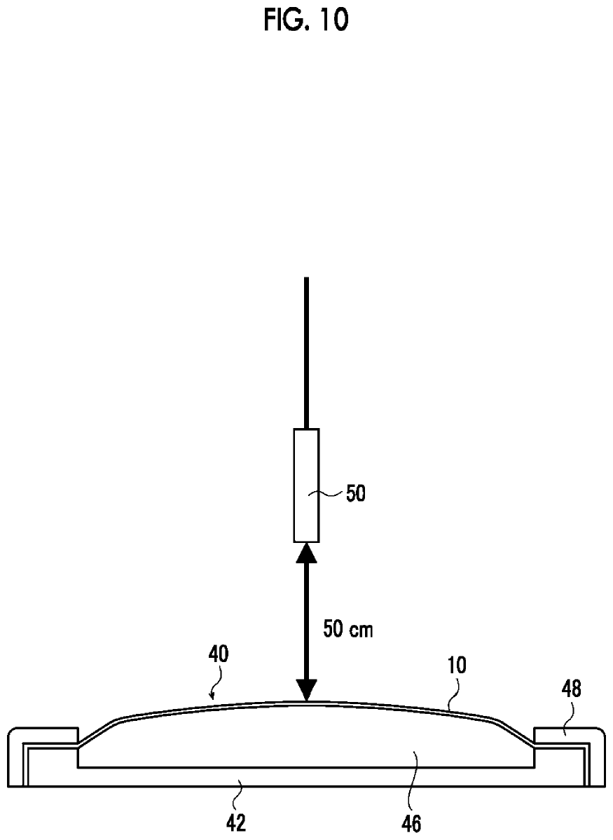

A 1 kHz sine wave was input to the produced piezoelectric speaker as an input signal through a power amplifier, and the sound pressure [dB] was measured with a microphone 50 placed at a distance of 50 cm from the center of the speaker as conceptually shown in FIG. 10.

The sound pressure (initial sound pressure) after 30 seconds after the start of the sound output from the piezoelectric speaker was defined as the sound pressure measurement result of the target piezoelectric speaker.

The results are shown in the table.

TABLE 1

| | Pressure of | Thickness of | Elastic recovery amount | | | Evaluation |
|---|---|---|---|---|---|---|
| | calender | electrode layer | Piezoelectric | Protective | | Sound |
| | treatment [MPa] | [nm] | layer [nm] | layer [nm] | Ratio D | pressure [dB] |
| Example 1 | 280 | 20 | 35 | 130 | 0.27 | 75.8 |
| Example 2 | 180 | 20 | 45 | 130 | 0.35 | 80.3 |
| Example 3 | 158 | 20 | 50 | 130 | 0.38 | 82.5 |
| Example 4 | 130 | 20 | 65 | 130 | 0.50 | 83.5 |
| Example 5 | 100 | 20 | 100 | 130 | 0.77 | 83.6 |
| Example 6 | 73 | 20 | 147 | 130 | 1.13 | 82.9 |
| Example 7 | 70 | 20 | 155 | 130 | 1.19 | 82.0 |
| Example 8 | 130 | 10 | 65 | 130 | 0.50 | 76.4 |
| Example 9 | 130 | 35 | 65 | 130 | 0.50 | 83.9 |
| Example 10 | 130 | 50 | 65 | 130 | 0.50 | 84.1 |
| Comparative | 300 | 20 | 20 | 130 | 0.15 | 69.9 |
| Example 1 | | | | | | |
| Comparative | 50 | 20 | 170 | 130 | 1.31 | 71.4 |
| Example 2 | | | | | | |

As shown in the above table, in the piezoelectric films according to the embodiment of the present invention, in which the ratio D of the elastic recovery amount between the piezoelectric layer and the protective layer, which were obtained by the nanoindentation measurement, was in a range of 0.27 to 1.19, a high sound pressure of more than 75 dB was obtained in a case of being formed into a speaker.

Among these, as shown in Example 2 and Example 7, a higher sound pressure of more than 80 dB was obtained by setting the ratio D of the elastic recovery amount between the piezoelectric layer and the protective layer, which were obtained by the nanoindentation measurement, to be a preferred range of 0.35 to 1.19. In particular, as shown in Examples 3 to 6, a further higher sound pressure was obtained by setting the ratio D of the elastic recovery amount between the piezoelectric layer and the protective layer, which were obtained by the nanoindentation measurement, to be a more preferred range of 0.38 to 1.13.

In addition, as shown in Example 4 and Examples 8 to 10, a high sound pressure of more than 80 dB was obtained by setting the thickness of the electrode layer to 20 nm or more. Furthermore, a higher sound pressure was obtained by setting the thickness of the electrode layer to be a more preferred thickness of 35 nm, and a further higher sound pressure was obtained by setting the thickness thereof to be a still more preferred range of 50 nm.

On the contrary, in Comparative Examples in which the ratio D of the elastic recovery amount by the nanoindentation measurement was less than 0.27 or more than 1.19, it was considered that the interlayer peeling of the electrode layer, the cracking and breakage, and the like occurred, resulting in low sound pressure in a case of being formed into a speaker.

From the above results, the effect of the present invention is clear.

The present invention can be suitably used for electroacoustic transducers such as a speaker, vibration sensors, and the like.

### EXPLANATION OF REFERENCES

10: piezoelectric film
12: piezoelectric layer
14: first electrode layer
16: second electrode layer
18: first protective layer
20: second protective layer
24: matrix
26: piezoelectric particle
34, 38: sheet-like material
36: piezoelectric multilayer body
40: piezoelectric speaker
42: case
46: viscoelastic support
48: frame
50: microphone
60, 62: heating roller pair

What is claimed is:

1. A piezoelectric film comprising:
a piezoelectric layer which contains piezoelectric particles in a matrix containing a polymer material;
electrode layers which are provided on both surfaces of the piezoelectric layer; and
protective layers which are provided on surfaces of the electrode layers,
wherein, in a case where a ratio D between an elastic recovery amount of the piezoelectric layer and an elastic recovery amount of the protective layer, which are obtained by a nanoindentation measurement, is determined as “ratio D of elastic recovery amount=elastic recovery amount of piezoelectric layer/elastic recovery amount of protective layer”, the ratio D of the elastic recovery amount satisfies
0.27≤D≤1.19.

2. The piezoelectric film according to claim 1,
wherein the ratio D of the elastic recovery amount satisfies
0.35≤D≤1.19.

3. The piezoelectric film according to claim 1,
wherein a thickness of the electrode layer is 20 nm or more.

4. The piezoelectric film according to claim 1,
wherein the piezoelectric film is polarized in a thickness direction.

5. The piezoelectric film according to claim 1,
wherein the polymer material is a polymer material having a cyanoethyl group.

6. The piezoelectric film according to claim 5,
wherein the polymer material is cyanoethylated polyvinyl alcohol.

7. A laminated piezoelectric element obtained by laminating a plurality of layers of the piezoelectric films according to claim 1.

8. The laminated piezoelectric element according to claim 7,
wherein the piezoelectric film is polarized in a thickness direction, and
polarization directions of adjacent piezoelectric films are opposite to each other.

9. The laminated piezoelectric element according to claim 7,
wherein the plurality of layers of the piezoelectric films are laminated by folding the piezoelectric film one or more times.

10. The laminated piezoelectric element according to claim 7, further comprising:
a bonding layer which bonds adjacent piezoelectric films.

11. The piezoelectric film according to claim 2,
wherein a thickness of the electrode layer is 20 nm or more.

12. The piezoelectric film according to claim 2,
wherein the piezoelectric film is polarized in a thickness direction.

13. The piezoelectric film according to claim 2,
wherein the polymer material is a polymer material having a cyanoethyl group.

14. The piezoelectric film according to claim 13,
wherein the polymer material is cyanoethylated polyvinyl alcohol.

15. A laminated piezoelectric element obtained by laminating a plurality of layers of the piezoelectric films according to claim 2.

16. The laminated piezoelectric element according to claim 15,
wherein the piezoelectric film is polarized in a thickness direction, and
polarization directions of adjacent piezoelectric films are opposite to each other.

17. The laminated piezoelectric element according to claim 8,
wherein the plurality of layers of the piezoelectric films are laminated by folding the piezoelectric film one or more times.

18. The laminated piezoelectric element according to claim 8, further comprising:
a bonding layer which bonds adjacent piezoelectric films.

19. The piezoelectric film according to claim 3,
wherein the piezoelectric film is polarized in a thickness direction.

20. The piezoelectric film according to claim 3,
wherein the polymer material is a polymer material having a cyanoethyl group.
